(19) United States
(12) Patent Application Publication
(10) Pub. No.: US 2024/0128234 A1
(43) Pub. Date: Apr. 18, 2024

(54) SEMICONDUCTOR PACKAGE

(71) Applicant: SAMSUNG ELECTRONICS CO., LTD., Suwon-si (KR)

(72) Inventor: JUNGPIL LEE, SUWON-SI (KR)

(21) Appl. No.: 18/222,567

(22) Filed: Jul. 17, 2023

(30) Foreign Application Priority Data
Oct. 14, 2022 (KR) 10-2022-0132396

(51) Int. Cl. H01L 25/065; H01L 23/00; H01L 23/31; H10B 80/00

(52) U.S. Cl. CPC H01L 25/0657; H01L 23/3128; H01L 24/08; H10B 80/00; H01L 2224/08145; H01L 2225/06506; H01L 2225/0651; H01L 2225/06562

(57) ABSTRACT

A semiconductor package includes semiconductor structures stacked in a stepwise manner. Each of the semiconductor structures may include a lower structure, an upper structure on the lower structure, and an insulating layer provided on a bottom surface of the upper structure to be in contact with at least a portion of side surfaces of the lower structure. An area of the lower structure may be smaller than an area of the upper structure, when viewed in a plan view, and a side surface of the insulating layer may be vertically aligned to a side surface of the upper structure.

### CROSS-REFERENCE TO RELATED APPLICATIONS

This U.S. non-provisional patent application claims priority under 35 U.S.C. § 119 to Korean Patent Application No. 10-2022-0132396, filed on Oct. 14, 2022, in the Korean Intellectual Property Office, the entire contents of which are hereby incorporated by reference.

### BACKGROUND OF THE INVENTION

The present disclosure relates to a semiconductor package, and in particular, to a semiconductor package that includes stacked semiconductor structures.

A semiconductor package is configured to easily use an integrated-circuit chip as a part of an electronic product. In general, the semiconductor package includes a printed circuit board (PCB) and a semiconductor chip, which is mounted on the PCB and is electrically connected to the PCB using bonding wires or bumps. With the development of the electronic industry, various studies are currently being conducted to realize a highly-reliable, highly-integrated, and small-sized semiconductor package.

### SUMMARY OF THE INVENTION

An exemplary embodiment of the inventive concept provides a semiconductor package with improved yield and productivity.

Another exemplary embodiment of the inventive concept provides a semiconductor package with improved thermal and structural stability.

According to an exemplary embodiment of the inventive concept, a semiconductor package may include semiconductor structures stacked in a stepwise manner Each of the semiconductor structures may include a lower structure, an upper structure on the lower structure, and an insulating layer provided on a bottom surface of the upper structure to be in contact with at least a portion of side surfaces of the lower structure. An area of the lower structure may be smaller than an area of the upper structure, when viewed in a plan view, and a side surface of the insulating layer may be vertically aligned to a side surface of the upper structure.

According to an exemplary embodiment of the inventive concept, a semiconductor package may include a substrate including substrate pads provided on a top surface thereof, substrate connection terminals provided on a bottom surface of the substrate, semiconductor structures stacked on the substrate, the semiconductor structures including chip pads on top surfaces of the semiconductor structures, bonding wires connecting the substrate pads to the chip pads, and a mold layer provided on the substrate to cover the semiconductor structures. Each of the semiconductor structures may include a lower structure, an upper structure disposed on the lower structure, the lower structure exposing a portion of a bottom surface of the upper structure, and an insulating layer provided on the exposed portion of the bottom surface of the upper structure. The semiconductor package may further include a supporter, which is disposed between a side surface of the insulating layer and one of side surfaces of the lower structure and is buried in the insulating layer.

According to an exemplary embodiment of the inventive concept, a semiconductor package may include semiconductor structures stacked in a stepwise manner Each of the semiconductor structures may include a cell array structure, a peripheral circuit structure disposed on the cell array structure, and an insulating layer provided on the cell array structure to enclose a side surface of the peripheral circuit structure. The cell array structure may include electrode layers stacked on a first substrate, a channel region provided to vertically penetrate the electrode layers, a first interlayer insulating layer covering the electrode layers and the channel region, and first chip pads, which are exposed to the exterior of the first interlayer insulating layer and are connected to the electrode layers and the channel region. The peripheral circuit structure may include at least one transistor provided on a second substrate, a second interlayer insulating layer covering the transistor, and second chip pads, which are exposed to the exterior of the second interlayer insulating layer and are connected to the transistor. The first and second chip pads may be in contact with each other to form a single entity.

### BRIEF DESCRIPTION OF THE DRAWINGS

FIG. 1 is a sectional view illustrating a semiconductor package according to an exemplary embodiment of the inventive concept.

FIG. 2 is a plan view illustrating a semiconductor structure according to an exemplary embodiment of the inventive concept.

FIG. 3 is a plan view illustrating a semiconductor structure according to an exemplary embodiment of the inventive concept.

FIG. 4 is an enlarged sectional view illustrating a portion ‘A’ of FIG. 1.

FIG. 5 is a sectional view illustrating a semiconductor package according to an exemplary embodiment of the inventive concept.

FIG. 6 is a plan view illustrating a semiconductor structure according to an exemplary embodiment of the inventive concept.

FIG. 7 is a plan view illustrating a semiconductor structure according to an exemplary embodiment of the inventive concept.

FIG. 8 is a diagram schematically illustrating an electronic system including a semiconductor structure according to an exemplary embodiment of the inventive concept.

FIG. 9 is a sectional view illustrating a semiconductor structure according to an exemplary embodiment of the inventive concept.

FIGS. 10 to 17 are sectional views illustrating a method of fabricating a semiconductor package, according to an exemplary embodiment of the inventive concept.

### DETAILED DESCRIPTION OF THE PREFERRED EMBODIMENTS

Exemplary embodiments of the inventive concepts will now be described more fully with reference to the accompanying drawings, in which such exemplary embodiments are shown.

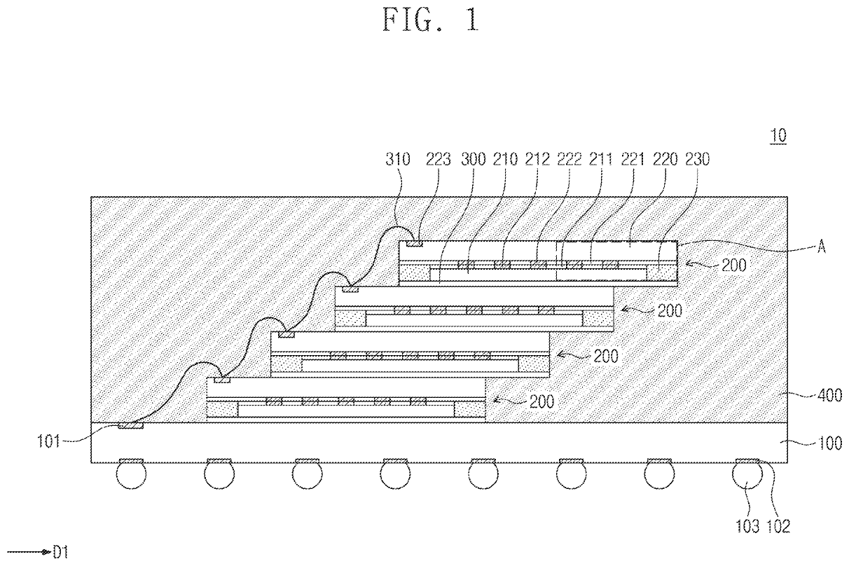

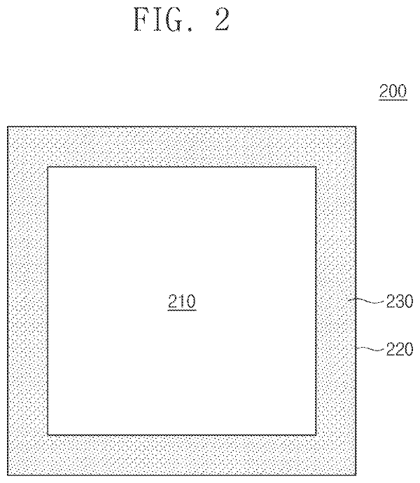

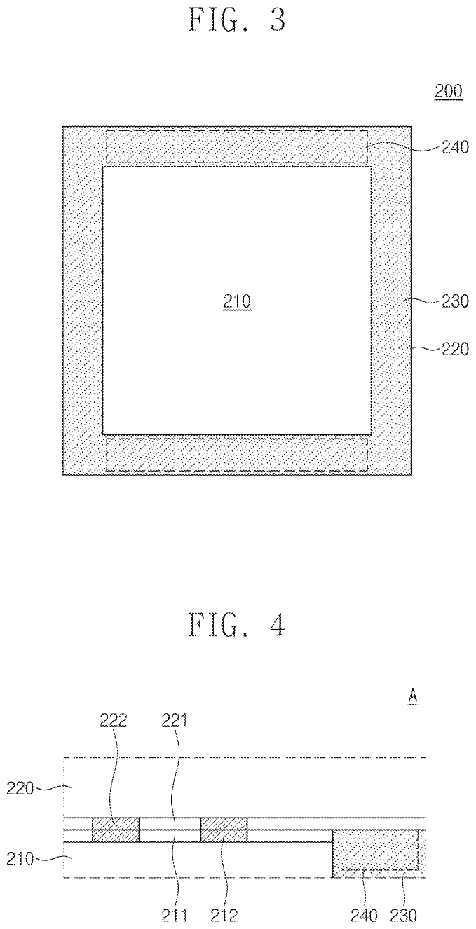

FIG. 1 is a sectional view illustrating a semiconductor package according to an exemplary embodiment of the inventive concept. FIGS. 2 and 3 are plan views, each of which illustrates a semiconductor structure according to an exemplary embodiment of the inventive concept. FIG. 4 is an enlarged sectional view illustrating a portion ‘A’ of FIG. 1.

Referring to FIGS. 1 to 4, a semiconductor package 10 may include a substrate 100, semiconductor structures 200, bonding wires 310, and a mold layer 400.

A substrate 100 may be provided. The substrate 100 may be a printed circuit board (PCB). The substrate 100 may have a structure, in which insulating layers and interconnection layers are alternately stacked. At least one first substrate pad 101 may be disposed on a top surface of the substrate 100. The first substrate pad 101 may be exposed to the exterior of the substrate 100 near the top surface of the substrate 100. Second substrate pads 102 may be disposed on a bottom surface of the substrate 100. The second substrate pads 102 may be exposed to the exterior of the substrate 100 near the bottom surface of the substrate 100. The first substrate pad 101 and the second substrate pad 102 may be electrically connected to each other through an interconnection layer. In the present specification, the expression “electrically connected or coupled” may be used to describe a case, in which two or more elements are directly connected/coupled to each other or are indirectly connected or coupled to each other via another conductive element. The first substrate pad 101 and the second substrate pads 102 may be formed of, or include a metallic material (e.g., copper (Cu), aluminum (Au), and/or nickel (Ni) or the like).

Outer connection terminals 103 may be disposed on the bottom surface of the substrate 100. The outer connection terminals 103 may be laterally spaced apart from each other. In more specific detail, the outer connection terminals 103 may be disposed on the second substrate pads 102 near the bottom surface of the substrate 100. The outer connection terminals 103 may be coupled to the second substrate pads 102. The outer connection terminals 103 may include solder balls or solder bumps. The outer connection terminals 103 may be formed of, or include at least one of tin (Sn), silver (Ag), copper (Cu), nickel (Ni), bismuth (Bi), indium (In), antimony (Sb), cerium (Ce), or any alloys thereof. Depending on the kind of the outer connection terminals 103, the semiconductor package 10 may be provided in the form of a ball-grid array (BGA) structure, a fine ball-grid array (FBGA) structure, or a land grid array (LGA) structure.

The semiconductor structures 200 may be provided on the substrate 100. The semiconductor structures 200 may be spaced apart from the first substrate pad 101 in a first direction D1 parallel to the substrate 100. The semiconductor structures 200 may be disposed on the substrate 100 to form an offset stack structure. The semiconductor structures 200 may be disposed to be stacked in a stepwise manner inclined in the first direction D1. Since the semiconductor structures 200 are stacked in the stepwise manner, a top surface of each of the semiconductor structures 200 may be partially exposed to the exterior of the semiconductor structures 200. Also, the semiconductor structures 200 may be stacked to expose a second upper chip pad 223, which will be described below. Although an example, in which four semiconductor structures 200 are stacked on the substrate 100, is illustrated, the inventive concept is not limited to this example, and in an exemplary embodiment, the number of semiconductor structures 200 stacked on the substrate 100 may be variously modified.

For briefness sake, some technical features of the semiconductor structures 200 will be described based on one of the semiconductor structures 200.

The semiconductor structure 200 may include an upper structure 220, a lower structure 210, and an insulating layer 230.

The upper structure 220 may be a semiconductor chip. For example, the upper structure 220 may include a circuit layer, which is electrically connected to first upper chip pads 222. The circuit layer may be disposed adjacent to a bottom surface of the upper structure 220. In other words, the bottom surface of the upper structure 220 may correspond to an active surface of the upper structure 220. However, the inventive concept is not limited to this example, and in an exemplary embodiment, an active surface of the upper structure 220 may correspond to a top surface of the upper structure 220. The circuit layer may be a memory or logic circuit, which includes one or more transistors, or combinations thereof. Alternatively, the circuit layer may include a passive device (e.g., a resistor or a capacitor). Thus, the upper structure 220 may include a semiconductor chip including the circuit layer. For example, the upper structure 220 may include a cell array structure or a peripheral circuit structure. The upper structure 220 may further include an upper passivation layer 221, first upper chip pads 222, and at least one second upper chip pad 223.

The first upper chip pads 222 may be disposed on the bottom surface of the upper structure 220. The first upper chip pads 222 may be electrically connected to the circuit layer of the upper structure 220. The first upper chip pads 222 may be exposed to the exterior of the upper structure 220 near the bottom surface of the upper structure 220. The at least one second upper chip pad 223 may be disposed on the top surface of the upper structure 220. The second upper chip pad 223 may be electrically connected to the circuit layer of the upper structure 220. For example, the second upper chip pad 223 may be electrically connected to the circuit layer of the upper structure 220 through a via or the like, which is provided to vertically penetrate the upper structure 220. The second upper chip pad 223 may be exposed to the exterior of the upper structure 220 near the top surface of the upper structure 220. The first upper chip pads 222 and the second upper chip pad 223 may be formed of, or include a metallic material. In an exemplary embodiment, the first upper chip pads 222 and the second upper chip pad 223 may be formed of, or include copper (Cu).

The upper passivation layer 221 may be disposed on the bottom surface of the upper structure 220. The upper passivation layer 221 may be provided to enclose the first upper chip pads 222. The upper passivation layer 221 may also be provided to expose the first upper chip pads 222. A bottom surface of the upper passivation layer 221 may be coplanar with a bottom surface of the first upper chip pads 222. The upper passivation layer 221 may be formed of, or include an insulating material (e.g., silicon oxide (SiO), silicon nitride (SiN), or silicon carbon nitride (SiCN) or the like).

The lower structure 210 may be a semiconductor chip. For example, the lower structure 210 may include a circuit layer, which is electrically connected to first lower chip pads 212. The circuit layer may be disposed adjacent to a top surface of the lower structure 210. In other words, the top surface of the lower structure 210 may correspond to an active surface of the lower structure 210. However, the inventive concept is not limited to this example, and in an exemplary embodiment, the active surface of the lower structure 210 may correspond to a bottom surface of the lower structure 210. The circuit layer may be a memory or logic circuit, which includes one or more transistors, or combinations thereof. Alternatively, the circuit layer may include a passive device (e.g., a resistor or a capacitor). Thus, the lower structure 210 may be a semiconductor chip including the circuit layer. For example, the lower structure 210 may include a cell array structure or a peripheral circuit structure. The lower structure 210 may further include a lower passivation layer 211 and first lower chip pads 212.

The first lower chip pads 212 may be disposed on the top surface of the lower structure 210. The first lower chip pads 212 may be electrically connected to the circuit layer of the lower structure 210. The first lower chip pads 212 may be exposed to the exterior of the lower structure 210 near the top surface of the lower structure 210. The first lower chip pads 212 may be formed of, or include a metallic material. As an example, the first lower chip pads 212 may be formed of, or include copper (Cu).

The lower passivation layer 211 may be disposed on the top surface of the lower structure 210. The lower passivation layer 211 may be provided to enclose the first lower chip pads 212. The lower passivation layer 211 may also be provided to expose the first lower chip pads 212. A top surface of the lower passivation layer 211 may be coplanar with top surfaces of the first lower chip pads 212. The lower passivation layer 211 may be formed of, or include an insulating material (e.g., silicon oxide (SiO), silicon nitride (SiN), or silicon carbon nitride (SiCN) or the like).

The upper structure 220 may be disposed on the lower structure 210. The upper structure 220 may have a center region and an outer region enclosing the center region, when viewed in a plan view. The lower structure 210 may be disposed in the center region of the upper structure 220. For example, when viewed in a plan view, the lower structure 210 may be placed in the upper structure 220. An area of the upper structure 220 may be larger than an area of the lower structure 210. The lower structure 210 may be in contact with a portion (e.g., in the center region) of the bottom surface of the upper structure 220 and may be provided to expose another portion (e.g., in the outer region) of the bottom surface of the upper structure 220.

The upper structure 220 may be connected to the lower structure 210. In more specific detail, a portion of the upper passivation layer 221 of the upper structure 220 may be in contact with the lower passivation layer 211 of the lower structure 210. At an interface between the upper passivation layer 221 and the lower passivation layer 211, the first upper chip pads 222 of the upper structure 220 may be bonded to the first lower chip pads 212 of the lower structure 210. Here, the first lower and upper chip pads 212 and 222 may form an intermetal hybrid bonding structure. In the present disclosure, the hybrid bonding structure may mean a bonding structure which is formed by two materials, which are of the same kind and are fused at an interface therebetween. For example, the first lower and upper chip pads 212 and 222, which are bonded to each other, may have a continuous structure. There may be no observable or visible interface between the first lower and upper chip pads 212 and 222. The first lower and upper chip pads 212 and 222 may be formed of the same material, and there may be no observable or visible interface between the first lower and upper chip pads 212 and 222. In other words, the first lower and upper chip pads 212 and 222 may be provided as a single element.

The insulating layer 230 may be provided on the bottom surface of the upper structure 220. In more specific detail, the insulating layer 230 may be provided on the bottom surface of the outer region of the upper structure 220, which is not covered with the lower structure 210. The insulating layer 230 may be in contact with side surfaces of the lower structure 210. The insulating layer 230 may cover the side surfaces of the lower structure 210. When viewed in a plan view, the insulating layer 230 may be provided to enclose the lower structure 210. The insulating layer 230 may be provided to expose the bottom surface of the lower structure 210. A bottom surface of the insulating layer 230 may be coplanar with the bottom surface of the lower structure 210. Alternatively, the insulating layer 230 may cover the bottom surface of the lower structure 210. A side surface of the insulating layer 230 may be vertically aligned with a side surface of the upper structure 220.

The insulating layer 230 may be formed of, or include a material, which has a thermal expansion coefficient that is similar or equal to that of the upper structure 220. In an exemplary embodiment, the insulating layer 230 may be formed of, or include a material, which has a thermal expansion coefficient that is smaller than that of the upper structure 220. The insulating layer 230 may be formed of, or include, for example, silicon oxide (SiO₂), silicon nitride (Si₃N₄), aluminum oxide (Al₂O₃), aluminum nitride (AlN), or boron nitride (BN). Alternatively, the insulating layer 230 may be formed of, or include an insulating polymer (e.g., epoxy-based molding compound (EMC) or the like).

In the case where the insulating layer 230 and the upper structure 220 have the same or similar thermal expansion coefficient, the insulating layer 230 and the upper structure 220 may exhibit a similar warpage behavior. Thus, it may be possible to prevent the semiconductor structure 200 from being deformed by heat that is supplied or generated in a process of fabricating or operating the semiconductor package. For example, it may be possible to prevent or suppress an upper portion (e.g., the upper structure 220) of the semiconductor structure 200 and a lower portion (e.g., the insulating layer 230 and the lower structure 210) of the semiconductor structure 200 from being distorted. In the case where the insulating layer 230 has a thermal expansion coefficient smaller than the upper structure 220, the insulating layer 230 may reduce the warpage issue in the upper structure 220. This may make it possible to realize a semiconductor package with improved structural stability.

A supporter 240 may be provided in the insulating layer 230. The supporter 240 may be buried in the insulating layer 230. Alternatively, the supporter 240 may be provided to have a bottom surface that is exposed to the exterior of the insulating layer 230 near the bottom surface of the insulating layer 230. Between a side surface of the lower structure 210 and a side surface of the insulating layer 230, the supporter 240 may be extended in a direction parallel to the top surface of the lower structure 210. In an exemplary embodiment, a plurality of supporters 240 may be provided. The supporters 240 may be formed of, or include silicon (Si). An example, in which two rectangular supporters 240 are disposed, is illustrated, the inventive concept is not limited to this example and the shape, size, and number of the supporters 240 may be variously modified.

According to an exemplary embodiment of the inventive concept, the supporter 240 provided in the insulating layer 230 may reduce a warpage issue in the semiconductor structure 200. For example, since the supporter 240 includes a material having a thermal expansion coefficient that is similar to the lower and upper structures 210 and 220, the warpage issue in the semiconductor structure 200 may be suppressed. This may make it possible to realize a semiconductor package with improved structural stability.

An adhesive layer 300 may be provided between the semiconductor structures 200. The semiconductor structure 200 may be attached to a top surface of an underlying semiconductor structure 200 through the adhesive layer 300. A portion of the adhesive layer 300 may be provided between the substrate 100 and the lowermost one of the semiconductor structures 200. The adhesive layer 300 may be formed of, or include an adhesive material.

The bonding wire 310 may be provided on the substrate 100. The bonding wire 310 may connect the substrate 100 to the semiconductor structures 200. In an exemplary embodiment, a plurality of bonding wires 310 may be provided. The bonding wires 310 may be in contact with the first substrate pad 101, which is provided on the top surface of the substrate 100, and the second upper chip pad 223, which is provided on the top surface of each of the semiconductor structures 200. The bonding wires 310 may be provided to electrically connect the substrate 100 to the lowermost one of the semiconductor structures 200 or to electrically connect adjacent ones of the semiconductor structures 200 to each other. FIG. 1 illustrates an example, in which the bonding wires 310 are provided to connect two adjacent ones of the semiconductor structures 200 and to connect the substrate 100 to the lowermost one of the semiconductor structures 200, but the inventive concept is not limited to this example. Each of the bonding wires 310 may be provided to connect a corresponding one of the semiconductor structures 200 to the substrate 100. The bonding wires 310 may be formed of, or include a metallic material.

The mold layer 400 may be provided on the substrate 100. The mold layer 400 on the substrate 100 may cover the semiconductor structures 200 and the bonding wires 310. A side surface of the mold layer 400 may be vertically aligned to the side surface of the substrate 100. The mold layer 400 may be formed of, or include an insulating polymer (e.g., epoxy-based molding compound (EMC) or the like).

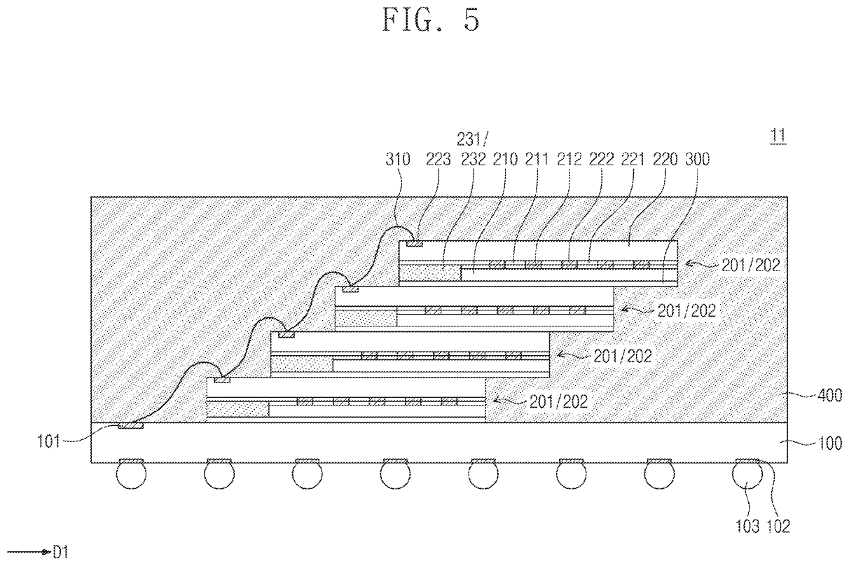

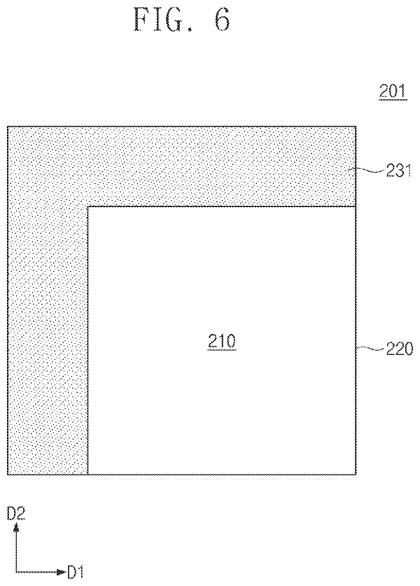

FIG. 5 is a sectional view illustrating a semiconductor package according to an exemplary embodiment of the inventive concept. FIG. 6 is a sectional view illustrating a semiconductor structure according to an exemplary embodiment of the inventive concept. In the following description, an element previously described with reference to FIGS. 1 to 4 may be identified by the same reference number without repeating an overlapping description thereof, for the sake of clarity and to avoid unnecessary redundancy.

Referring to FIGS. 5 and 6, a semiconductor package 11 may include the substrate 100, semiconductor structures 201 stacked on the substrate 100, the bonding wire 310, and the mold layer 400.

For conciseness, some technical features of the semiconductor structures 201 will be described based on one of the semiconductor structures 201.

The semiconductor structure 201 may include the upper structure 220, the lower structure 210, and an insulating layer 231.

The upper structure 220 may be disposed on the lower structure 210. The lower structure 210 may be disposed such that a side surface thereof is vertically aligned to a side surface of the upper structure 220. Two adjacent side surfaces of the lower structure 210 may be vertically aligned with two adjacent side surfaces of the upper structure 220. When viewed in a plan view, an area of the upper structure 220 may be larger than an area of the lower structure 210. The lower structure 210 may be provided to be in contact with a portion of the bottom surface of the upper structure 220 and to expose another portion of the bottom surface of the upper structure 220. The exposed portion of the bottom surface of the upper structure 220 may have the shape of the letter ‘L’.

The insulating layer 231 may be provided on the bottom surface of the upper structure 220. The insulating layer 231 may be provided on the bottom surface of the upper structure 220 exposed by the lower structure 210. The insulating layer 231 may be in contact with at least a portion of side surfaces of the lower structure 210. For example, the insulating layer 231 may cover two adjacent ones of the side surfaces of the lower structure 210. A portion of the insulating layer 231 may be extended in the first direction D1, and another portion of the insulating layer 231 may extend from an end of the portion in a second direction D2 that is substantially orthogonal to the first direction D1. The insulating layer 231 may be provided to have the shape of the letter ‘L’, when viewed in a plan view. The insulating layer 231 may be provided to expose the bottom surface of the lower structure 210. A bottom surface of the insulating layer 231 may be coplanar with the bottom surface of the lower structure 210. Alternatively, the insulating layer 231 may be provided to cover the bottom surface of the lower structure 210. A side surface of the insulating layer 231 may be vertically aligned to a portion of the side surface of the upper structure 220.

The insulating layer 231 may be formed of, or include a material whose thermal conductivity is higher than that of the upper structure 220. For example, the insulating layer 230 may be formed of, or include at least one of silicon oxide (SiO₂), silicon nitride (Si₃N₄), aluminum oxide (Al₂O₃), aluminum nitride (AlN), or boron nitride (BN). Alternatively, the insulating layer 231 may be formed of, or include an insulating polymer (e.g., epoxy-based molding compound (EMC) or the like).

According to an exemplary embodiment of the inventive concept, the insulating layer 231 may be formed of, or include a material having a higher thermal conductivity than the upper structure 220, and thus, heat, which is generated in the upper structure 220, may be more easily dissipated. Accordingly, a semiconductor package with improved thermal stability may be provided.

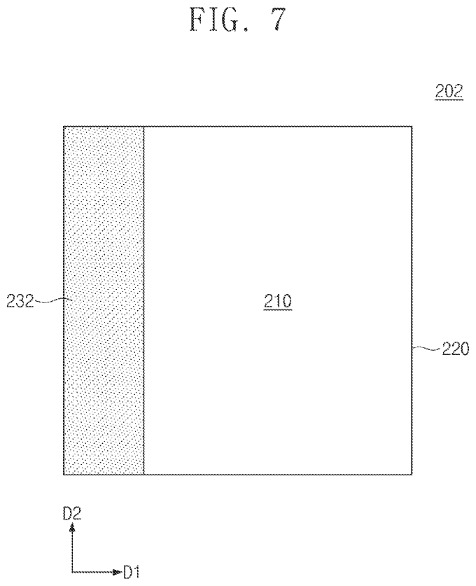

FIG. 7 is a sectional view illustrating a semiconductor structure according to an exemplary embodiment of the inventive concept.

Referring to FIGS. 5 and 7, semiconductor structures 202 may include the upper structure 220, the lower structure 210, and an insulating layer 232. Hereinafter, some technical features of the semiconductor structures 202 will be described based on one of the semiconductor structures 202, for ease of description.

The upper structure 220 may be disposed on the lower structure 210. The lower structure 210 may be disposed such that a side surface thereof is vertically aligned to a side surface of the upper structure 220. When viewed in a plan view, three side surfaces of the lower structure 210 may coincide with three side surfaces of the upper structure 220. When viewed in a plan view, an area of the upper structure 220 may be larger than an area of the lower structure 210. The lower structure 210 may be provided to be in contact with a portion of the bottom surface of the upper structure 220 and to expose another portion of the bottom surface of the upper structure 220. The exposed portion of the bottom surface of the upper structure 220 may have the shape of the letter ‘I’.

The insulating layer 232 may be provided on the bottom surface of the upper structure 220. The insulating layer 232 may be provided on the bottom surface of the upper structure 220 exposed by the lower structure 210. The insulating layer 232 may be disposed at a side of the lower structure 210. The insulating layer 232 may be in contact with at least a portion of the side surfaces of the lower structure 210. In an exemplary embodiment, the insulating layer 232 may cover one of the side surfaces of the lower structure 210. The insulating layer 232 may extend along one of the side surfaces of the upper structure 220 and in the second direction D2. The insulating layer 231 may have the shape of the letter ‘I’, when viewed in a plan view. A side surface of the insulating layer 232 may be vertically aligned to a portion of the side surface of the upper structure 220.

In the semiconductor packages according to an exemplary embodiment of the inventive concept, each of the semiconductor structures 200 and 201 may include the sub-structures 210 and 220, which are provided to have different planar areas, and the insulating layers 230, 231, and 232, which are used to compensate for a height difference between the sub-structures 210 and 220 caused by the difference in the planar area. In the case where the insulating layers 230, 231, and 232 are used to reduce the height difference between the sub-structures 210 and 220, it may be possible to easily stack the sub-structures 210 and 220, even when the sub-structures 210 and 220 have different planar sizes. This may make it possible to diversify the sizes of the sub-structures 210 and 220, if necessary, and to improve the production yield and productivity in a process of fabricating the instant semiconductor package. Furthermore, due to the insulating layers 230, 231, and 232, which are used to reduce the height difference between the sub-structures 210 and 220, it may be possible to realize a semiconductor package with improved structural and thermal stability.

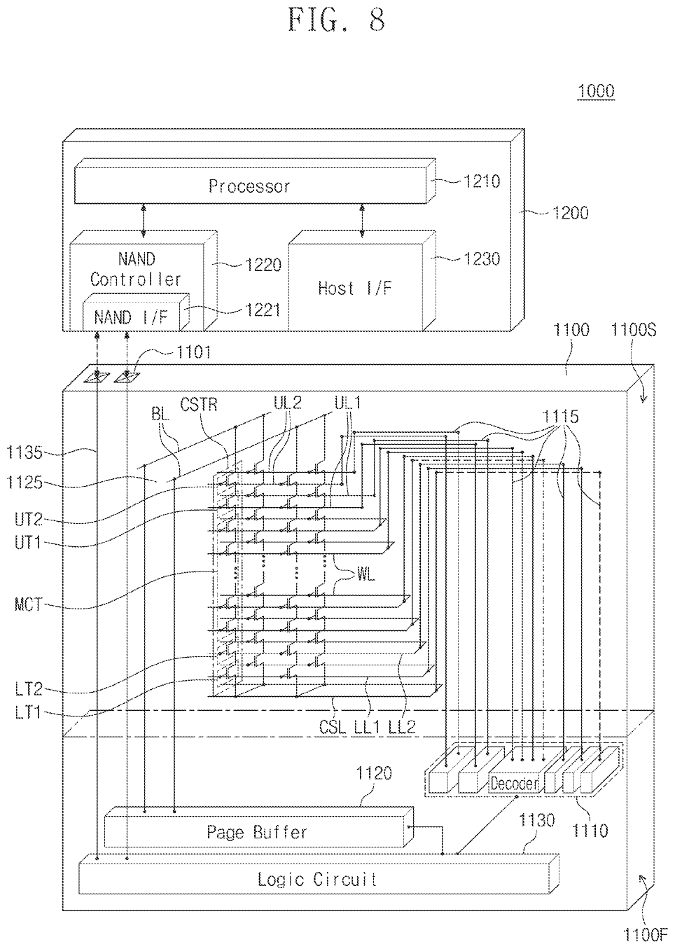

Hereinafter, an exemplary embodiment, in which the semiconductor package includes a VNAND chip, will be described with reference to FIGS. 8 and 9.

FIG. 8 is a diagram schematically illustrating an electronic system including a semiconductor structure according to an exemplary embodiment of the inventive concept.

Referring to FIG. 8, an electronic system 1000 according to an exemplary embodiment of the inventive concept may include a semiconductor device 1100 and a controller 1200, which are electrically connected to each other. The electronic system 1000 may be a storage device including one or more semiconductor devices 1100 or an electronic device including the storage device. For example, the electronic system 1000 may be a solid state drive (SSD) device, a universal serial bus (USB), a computing system, a medical system, or a communication system including one or more semiconductor devices 1100.

The semiconductor device 1100 may be a nonvolatile memory device (e.g., a NAND FLASH memory device). The semiconductor device 1100 may include a first structure 1100F and a second structure 1100S on the first structure 1100F. In an exemplary embodiment, the first structure 1100F may be disposed at a side of the second structure 1100S. The first structure 1100F maybe a peripheral circuit structure, which includes a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously modified, according to exemplary embodiments.

In another exemplary embodiment, the upper transistors UT1 and UT2 may include at least one string selection transistor, and the lower transistors LT1 and LT2 may include at least one ground selection transistor. The gate lower lines LL1 and LL2 may be used as gate electrodes of the lower transistors LT1 and LT2, respectively. The word lines WL may be used as gate electrodes of the memory cell transistors MCT, and the gate upper lines UL1 and UL2 may be used as gate electrodes of the upper transistors UT1 and UT2, respectively.

In yet another exemplary embodiment, the lower transistors LT1 and LT2 may include a lower erase control transistor LT1 and a ground selection transistor LT2, which are connected in series. The upper transistors UT1 and UT2 may include a string selection transistor UT1 and an upper erase control transistor UT2, which are connected in series. At least one of the lower and upper erase control transistors LT1 and UT2 may be used to perform an erase operation of erasing data in the memory cell transistors MCT using a gate-induced drain leakage (GIDL) phenomenon.

The common source line CSL, the first and second gate lower lines LL1 and LL2, the word lines WL, and the first and second gate upper lines UL1 and UL2 may be electrically connected to the decoder circuit 1110 through first connection lines 1115, which extend from the first structure 1100F to the second structure 1100S. The bit lines BL may be electrically connected to the page buffer 1120 through second connection lines 1125, which extend from the first structure 1100F to the second structure 1100S.

In the first structure 1100F, the decoder circuit 1110 and the page buffer 1120 may be configured to perform a control operation on at least a selected one of the memory cell transistors MCT. The decoder circuit 1110 and the page buffer 1120 may be controlled by the logic circuit 1130. The semiconductor device 1100 may communicate with the controller 1200 through an input/output pad 1101, which is electrically connected to the logic circuit 1130. The input/output pad 1101 may be electrically connected to the logic circuit 1130 through an input/output connection line 1135, which is provided in the first structure 1100F and extends to the second structure 1100S.

The controller 1200 may include a processor 1210, a NAND controller 1220, and a host interface 1230. In an exemplary embodiment, the electronic system 1000 may include a plurality of semiconductor devices 1100, and in this case, the controller 1200 may control the semiconductor devices 1100.

The processor 1210 may control overall operations of the electronic system 1000 including the controller 1200. The processor 1210 may be operated based on a specific firmware and may control the NAND controller 1220 to access the semiconductor device 1100. The NAND controller 1220 may include a NAND interface 1221, which is used to communicate with the semiconductor device 1100. The NAND interface 1221 may be used to transmit and receive control commands for controlling the semiconductor device 1100 and data to be written in or read from the memory cell transistors MCT of the semiconductor device 1100. The host interface 1230 may be configured to allow for communication between the electronic system 1000 and an external host. When a control command is received from an external host through the host interface 1230, the processor 1210 may control the semiconductor device 1100 in response to the control command.

FIG. 9 is a sectional view illustrating a semiconductor structure according to an exemplary embodiment of the inventive concept.

Referring to FIG. 9, a semiconductor structure 2000 may include a cell array structure CS and a peripheral circuit structure PS. In the exemplary embodiment of FIG. 9, the cell array structure CS may correspond to the upper structure 220 described with reference to FIG. 1, and the peripheral circuit structure PS may correspond to the lower structure 210 described with reference to FIG. 1. Alternatively, the cell array structure CS may correspond to the lower structure 210 described with reference to FIG. 1, and the peripheral circuit structure PS may correspond to the upper structure 220 described with reference to FIG. 1.

The semiconductor structure 2000 may include the cell array structure CS and the peripheral circuit structure PS. Each of the cell array structure CS and the peripheral circuit structure PS may include an outer pad bonding region PA, a word line bonding region WLBA, and a bit line bonding region BLBA.

In an exemplary embodiment, the cell array structure CS may include stacks ST, vertical structures VS, and connection interconnection structures CPLG, CL, WPLG, and PCL, which are provided on a first substrate 290. As an example, the cell array structure CS may correspond to the upper structure 220 described with reference to FIG. 1, and a portion of the cell array structure CS may correspond to the circuit layer of the upper structure 220. In the case where the cell array structure CS corresponds to the lower structure 210, a portion of the cell array structure CS may correspond to the circuit layer of the lower structure 210.

The first substrate 290 may be provided in the cell array structure CS. The first substrate 290 may be formed of, or include a semiconductor material. For example, the first substrate 290 may be a silicon substrate, a silicon-germanium substrate, a germanium substrate, or a single crystalline epitaxial layer grown on a single crystalline silicon substrate. As an example, the first substrate 290 may be a silicon wafer. In addition, the first substrate 290 may be formed of, or include a doped semiconductor material of a first conductivity type (e.g., p-type) and/or an undoped or intrinsic semiconductor material.

The stacks ST on the first substrate 290 may extend in the first direction D1 and may be arranged to be spaced apart from each other in a third direction D3 perpendicular to the first and second directions D1 and D2. Each of the stacks ST may include electrodes EL, which are vertically stacked on the first substrate 290, and insulating layers ILD, which are interposed therebetween. In the stacks ST, a thickness of each of the insulating layers ILD may be changed, depending on technical requirements for the semiconductor memory device. As an example, some of the insulating layers ILD may be formed to be thicker than the others. The insulating layers ILD may be formed of, or include silicon oxide (SiO). The electrodes EL may be formed of, or include at least one of conductive materials, semiconductor materials, metal silicide materials, metallic materials, and metal nitride materials, and may have a single- or multi-layered structure.

The stacks ST may extend from the bit line bonding region BLBA in the first direction D1 and may have a stepwise structure on the word line bonding region WLBA. Lengths of the electrodes EL of the stacks ST in the first direction D1 may decrease as a distance from the first substrate 290 increases. The stacks ST may be provided to form various stepwise structures on the word line bonding region WLBA.

In an exemplary embodiment, the semiconductor device may be a three-dimensional NAND FLASH memory device, and the cell strings CSTR of FIG. 8 may be integrated on the first substrate 290. In this case, the lowermost and uppermost ones of the electrodes EL in the stacks ST may be used as the gate electrodes of the selection transistors LT1 and UT2 of FIG. 8. For example, the uppermost one of the electrodes EL may serve as a gate electrode of the string selection transistor UT2 of FIG. 8, which is used to control an electric connection between the bit line BL and the vertical structures VS, and the lowermost one of the electrodes EL may serve as a gate electrode of the ground selection transistor LT1 of FIG. 8, which is used to control an electric connection between the common source line CSL of FIG. 8 and the vertical structures VS. The electrodes EL between the uppermost and lowermost ones may serve as control gate electrodes of memory cells and the word lines WL of FIG. 8 connecting the control gate electrodes to each other.

In the bit line bonding region BLBA, the vertical structures VS may penetrate the stacks ST and may be in contact with the first substrate 290. The vertical structures VS may be electrically connected to the first substrate 290. The vertical structures VS may be arranged in a specific direction or in a zigzag shape, when viewed in a plan view. Furthermore, dummy vertical structures (not shown) may be provided in the word line bonding region WLBA or the outer pad bonding region PA to have substantially the same structure as the vertical structures VS.

The vertical structures VS may be formed of, or include at least one of semiconductor materials (e.g., silicon (Si) and germanium (Ge)). In addition, the vertical structures VS may be formed of, or include a doped or undoped (e.g., intrinsic) semiconductor material. The vertical structures VS including the semiconductor material may be used as channel regions of the selection transistors LT1, LT2, UT1, and UT2 and the memory cell transistors MCT described with reference to FIG. 8. Bottom surfaces of the vertical structures VS may be located between top and bottom surfaces of the first substrate 290. A contact pad may be provided on the vertical structure VS or in an upper portion of the vertical structure VS and may be coupled to a bit line contact plug BPLG.

Each of the vertical structures VS may include a semiconductor pattern SP and a vertical insulating pattern VP, which are in contact with the first substrate 290. The semiconductor pattern SP may have a shape of hollow pipe or macaroni. The semiconductor pattern SP may have a bottom portion of a closed shape, and an inner space of the semiconductor pattern SP may be filled with a gapfill insulating pattern VI. The semiconductor pattern SP may be in contact with a top surface of the first substrate 290. The semiconductor pattern SP may be in an undoped state or may be doped to have the same conductivity type as the first substrate 290. The semiconductor pattern SP may have a polycrystalline or single-crystalline structure.

The vertical insulating pattern VP may be disposed between the stack ST and the vertical structures VS. The vertical insulating pattern VP may extend in the third direction D3 and may enclose a side surface of the vertical structure VS. In other words, the vertical insulating pattern VP may be shaped like a hollow pipe or macaroni with open top and bottom.

The vertical insulating pattern VP may include one or more layers. In an exemplary embodiment, the vertical insulating pattern VP may be a portion of a data storing layer. For example, the vertical insulating pattern VP may include a tunnel insulating layer, a charge storing layer, and a blocking insulating layer, which are used as a data storing layer of a NAND FLASH memory device. For example, the charge storing layer may be a trap insulating layer, a floating gate electrode, or an insulating layer with conductive nano dots. In more detail, the charge storing layer may include at least one of a silicon nitride layer, a silicon oxynitride layer, a silicon-rich nitride layer, a nanocrystalline silicon layer, or a laminated trap layer. The tunnel insulating layer may be formed of at least one of materials, whose band gaps are greater than that of the charge storing layer, and the blocking insulating layer may be formed of at least one of high-k dielectric materials (e.g., aluminum oxide (Al₂O₃) and hafnium oxide (Hf₂O)). In certain exemplary embodiments, the vertical insulating layer may include at least one layer (not shown) exhibiting a phase-changeable property or a variable resistance property.

A horizontal insulating pattern HP may be provided between a side surface of the electrode EL and the vertical insulating pattern VP. The horizontal insulating pattern HP may extend from the side surface of the electrode EL to cover top and bottom surfaces of the electrode EL. The horizontal insulating pattern HP may be a part of the data storing layer of the NAND FLASH memory device and may include the charge storing layer and the blocking insulating layer. Alternatively, the horizontal insulating pattern HP may include the blocking insulating layer.

Common source regions CSR may be respectively disposed between adjacent ones of the stacks ST and in the first substrate 290. The common source regions CSR may extend parallel to the stacks ST or in the first direction D1. The common source regions CSR may be formed by doping the first substrate 290 with impurities of a second conductivity type. The common source regions CSR may contain, for example, n-type impurities (e.g., arsenic (As) or phosphorus (P)).

A common source plug CSP may be coupled to the common source region CSR. A sidewall insulating spacer SSP may be interposed between the common source plug CSP and the stacks ST. During the read or program operations of the three-dimensional NAND FLASH memory device, a ground voltage may be applied to the common source region CSR through the common source plug CSP.

A first insulating gapfill layer 280 may be provided on the first substrate 290 to cover end portions of the electrodes EL, which are disposed in a stepwise shape. A first interlayer insulating layer 281 may be provided to cover top surfaces of the vertical structures VS, and a second interlayer insulating layer 282 may be provided on the first interlayer insulating layer 281 to cover a top surface of the common source plug CSP.

The bit lines BL may be disposed on the second interlayer insulating layer 282 to cross the stacks ST and to extend in the second direction D2. The bit line BL may be electrically connected to the vertical structure VS through the bit line contact plug BPLG. Some of the bit lines BL may correspond to pads, which are used for electric connection with the peripheral circuit structure PS. The pads may correspond to the first upper chip pads 222 described with reference to FIG. 1. In another exemplary embodiment, the pads may correspond to the first lower chip pads 212 described with reference to FIG. 1.

An interconnection structure may be provided on the stepwise end of the stacks ST to electrically connect the cell array structure CS to the peripheral circuit structure PS. The interconnection structure may include cell contact plugs CPLG, which are provided to penetrate the first insulating gapfill layer 280 and the first and second interlayer insulating layers 281 and 282 and are respectively coupled to the end portions of the electrodes EL, and connection lines CL, which are provided on the second interlayer insulating layer 282 and are respectively coupled to the cell contact plugs CPLG. In addition, the interconnection structure may further include well contact plugs WPLG, which are coupled to well pick-up regions PUR in the first substrate 290, and peripheral connection lines PCL, which are connected to the well contact plugs WPLG.

The well pick-up regions PUR may be disposed in portions of the first substrate 290, which are respectively located at opposite sides of each of the stacks ST. The well pick-up regions PUR may have the same conductivity type as the first substrate 290, and an impurity concentration of the well pick-up region PUR may be higher than an impurity concentration of the first substrate 290. For example, the well pick-up regions PUR may include a high concentration of p-type impurities (e.g., boron (B)). In an exemplary embodiment, during an erase operation of a three-dimensional NAND FLASH memory device, an erase voltage may be applied to the well pick-up regions PUR through a connection contact plug PPLG and the well contact plug WPLG.

A third interlayer insulating layer 283 may be provided on the second interlayer insulating layer 282 to enclose the bit lines BL, the connection lines CL, and the peripheral connection lines PCL. The third interlayer insulating layer 283 may be provided to expose top surfaces of the bit lines BL, top surfaces of the connection lines CL, and top surfaces of the peripheral connection lines PCL. The bit lines BL, the connection lines CL, and the peripheral connection lines PCL may constitute a cell array interconnection layer 284. The bit lines BL, the connection lines CL, and the peripheral connection lines PCL may correspond to pads of the cell array structure CS, which are electrically connected to the peripheral circuit structure PS. The third interlayer insulating layer 283 may correspond to the upper passivation layer 221 described with reference to FIG. 1. In another exemplary embodiment, the third interlayer insulating layer 283 may correspond to the lower passivation layer 211 described with reference to FIG. 1.

The peripheral circuit structure PS may be disposed on the cell array structure CS. The peripheral circuit structure PS may include a second substrate 270, peripheral circuits, which are integrated on the second substrate 270, and a second insulating gapfill layer 264 covering the peripheral circuits.

The second substrate 270 may be provided in the peripheral circuit structure PS. The second substrate 270 may be a silicon substrate, a silicon-germanium substrate, a germanium substrate, or a single crystalline epitaxial layer grown on a single crystalline silicon substrate. In an exemplary embodiment, the second substrate 270 may be a silicon substrate of a first conductivity type (e.g., p-type) and may include well regions.

The peripheral circuits may include the row and column decoders, the page buffer, and the control circuit, as described above, and may include NMOS and PMOS transistors, low- and high-voltage transistors, and resistors, which are integrated on the second substrate 270. In more specific detail, the peripheral circuits may include a pre-charge control circuit, which is used to control data program steps on a plurality of memory cells and to control some cell strings.

In still more detail, a device isolation layer 265 may be formed in the second substrate 270 to define active regions. Peripheral gate electrodes 266 may be disposed on the active regions of the second substrate 270, and a gate insulating layer may be interposed therebetween. Source/drain regions 267 may be provided in portions of the second substrate 270, which are placed at both sides of the peripheral gate electrodes 266.

A peripheral interconnection layer 260 may be connected to the peripheral circuits on the second substrate 270. The peripheral interconnection layer 260 may include peripheral interconnection lines 263 and peripheral contact plugs 237. The peripheral interconnection lines 263 may be electrically connected to the peripheral circuits through the peripheral contact plugs 237. For example, the peripheral circuit plugs 237 and the peripheral interconnection lines 263 may be coupled to the NMOS and PMOS transistors.

The second insulating gapfill layer 264 may cover the peripheral gate electrodes 266, the peripheral circuit plugs 237, and the peripheral interconnection lines 263. The second insulating gapfill layer 264 may correspond to the lower passivation layer 211 described with reference to FIG. 1. In an exemplary embodiment, the second insulating gapfill layer 264 may correspond to the upper passivation layer 221 described with reference to FIG. 1.

The second insulating gapfill layer 264 may include a plurality of insulating layers which are sequentially stacked. For example, the second insulating gapfill layer 264 may be formed of, or include at least one of silicon oxide (SiO), silicon nitride (SiN), silicon oxynitride (SiON), and/or low-k dielectric materials.

The peripheral interconnection layer 260 may further include exposed interconnection lines 261, which are exposed to the exterior of the second insulating gapfill layer 264 near a bottom surface of the second insulating gapfill layer 264. The exposed interconnection lines 261 may correspond to pads, which are used to electrically connect the peripheral circuit structures PS to the cell array structure CS. The pads may correspond to the first lower chip pads 212 described with reference to FIG. 1. In an exemplary embodiment, the pads may correspond to the first upper chip pads 222 described with reference to FIG. 1. The exposed interconnection lines 261 may be disposed to correspond to the bit lines BL.

In an exemplary embodiment, the peripheral interconnection lines 263 and the peripheral circuit plugs 237 may be formed of tungsten (W) with a relatively high resistance, and the exposed interconnection lines 261 may be formed of copper (Cu) with a relatively low resistance.

In the present disclosure, examples, in which the peripheral interconnection lines 263 are disposed in a single layer, have been illustrated, but the inventive concept is not limited to such examples. For example, the peripheral interconnection lines 263 may be stacked to form a multi-layered structure, and in another exemplary embodiment, at least one of the peripheral interconnection lines 263 may be formed of a low resistance material (e.g., aluminum (Al)) whose electrical resistance is lower than that of a material (e.g., copper (Cu)) of the exposed interconnection lines 261.

The cell array structure CS and the peripheral circuit structure PS may be in direct contact with each other. When viewed in a plan view, an area of the cell array structure CS may be larger than an area of the peripheral circuit structure PS. Accordingly, a portion of a top surface of the cell array structure CS may be in contact with the peripheral circuit structure PS, and the other portion may be exposed. For example, as shown in FIG. 9, a portion of the cell array interconnection layer 284 of the cell array structure CS may be in contact with the peripheral interconnection layer 260 of the peripheral circuit structure PS. For example, a portion of the third interlayer insulating layer 283 may be in contact with the second insulating gapfill layer 264, and the bit lines BL, the connection lines CL, and at least some of the peripheral connection lines PCL may be connected to the exposed interconnection lines 261. Here, the cell array interconnection layer 284 and the peripheral interconnection layer 260 may form an intermetal hybrid bonding structure. Each of the bit lines BL, the connection lines CL, and the peripheral connection lines PCL may be continuously connected to a corresponding one of the exposed interconnection lines 261 to form a continuous structure, and in such case, an interface between the exposed interconnection lines 261 and each of the bit lines BL, the connection lines CL and the peripheral connection lines PCL may not be observable or visible.

The insulating layer 230 may be provided on the cell array structure CS. The insulating layer 230 may correspond to the insulating layer described with reference to FIGS. 1 to 7. The insulating layer 230 may be provided on the exposed top surface of the cell array structure CS. The insulating layer 230 may be in contact with at least a portion of side surfaces of the peripheral circuit structure PS. When viewed in a plan view, the insulating layer 230 may enclose the peripheral circuit structure PS. In an exemplary embodiment, the insulating layer 230 may be in contact with one or two adjacent ones of the side surfaces of the peripheral circuit structure PS. A top surface of the insulating layer 230 may be coplanar with a top surface of the peripheral circuit structure PS. The side surface of the insulating layer 230 may be vertically aligned to a side surface of the cell array structure CS.

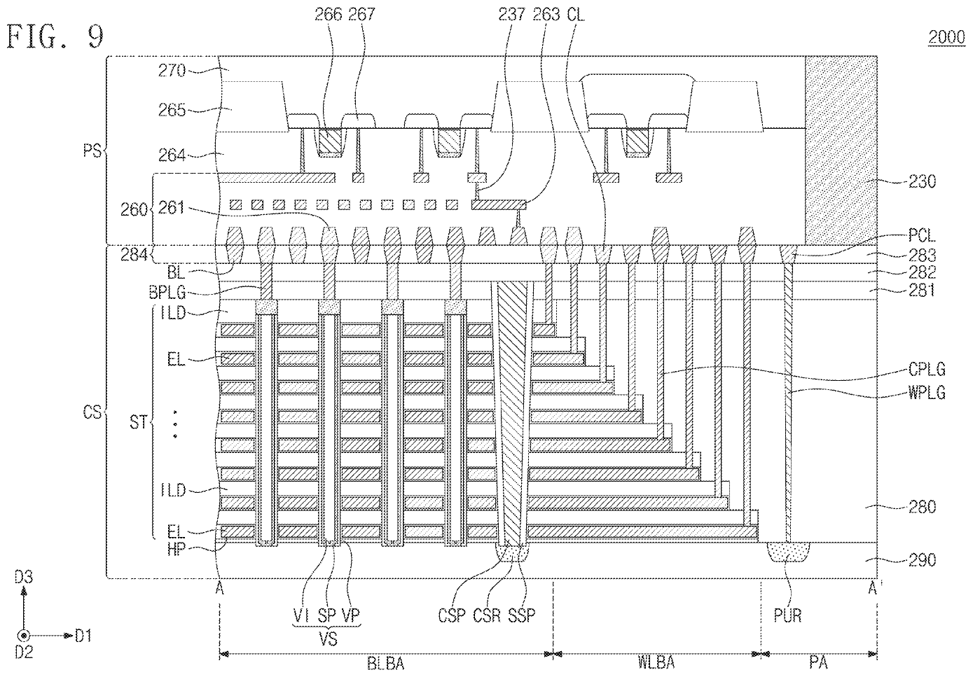

FIGS. 10 to 17 are sectional views illustrating a method of fabricating a semiconductor package according to an exemplary embodiment of the inventive concept.

Referring to FIG. 10, a first wafer 210a may be provided. Although not shown, a circuit layer may be formed on the first wafer 210a. The circuit layer may be a memory or logic circuit, which includes one or more transistors, or combinations thereof. Alternatively, the circuit layer may include a passive device (e.g., a resistor or a capacitor). The lower passivation layer 211 may be formed on the first wafer 210a to cover the circuit layer. The lower passivation layer 211 may cover a top surface of the first wafer 210a. Openings may be formed by performing a patterning process on the lower passivation layer 211. Although not shown, a metal layer may be formed to cover the lower passivation layer 211 and to cover the openings. The first lower chip pads 212 may be formed in the lower passivation layer 211 through a planarization process on the metal layer. The planarization process may be performed by, for example, a chemical mechanical polishing (CMP) process. The planarization process may be performed to expose a top surface of the lower passivation layer 211. Lower structures may be formed by performing a sawing process on the first wafer 210a. In an exemplary embodiment, the lower structures may be separated from each other by performing the sawing process on the first wafer 210a.

Referring to FIG. 11, a second wafer 220a may be provided. The upper passivation layer 221 may be formed on the second wafer 220a. The upper passivation layer 221 may cover a top surface of the second wafer 220a. Openings may be formed by performing a patterning process on the upper passivation layer 221. Although not shown, a metal layer may be formed to cover the upper passivation layer 221 and to fill the openings. The first upper chip pads 222 may be formed in the upper passivation layer 221 through a planarization process on the metal layer.

Opening may be formed by performing a patterning process on a passivation layer (not shown) on a bottom surface of the second wafer 220a. Although not shown, a metal layer may be formed to fill the opening. At least one second upper chip pad 223 may be formed on the bottom surface of the second wafer 220a through a planarization process on the metal layer.

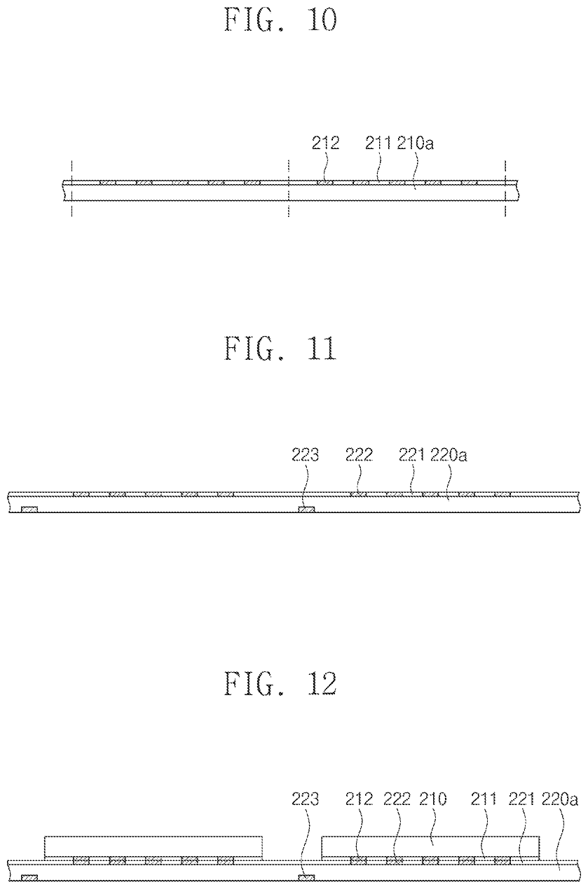

Referring to FIG. 12, the lower structures 210 may be disposed on the second wafer 220a. By performing a test process on the lower structures 210, the lower structures 210 may be classified into good dies and bad dies. The upper passivation layer 221 on the second wafer 220a may be in contact with the lower passivation layer 211 of the lower structure 210. Here, the first lower chip pads 212 of the lower structure 210 may be connected to the first upper chip pads 222 of the second wafer 220a. The first lower and upper chip pads 212 and 222 may be connected to each other to form an intermetal hybrid bonding structure. For example, the first lower and upper chip pads 212 and 222 may be formed of the same material (e.g., copper (Cu)), and in this case, the first lower and upper chip pads 212 and 222 may be bonded to each other by an intermetal hybrid bonding process caused by a surface activation phenomenon at an interface of the first lower and upper chip pads 212 and 222. The first lower and upper chip pads 212 and 222, which are coupled to each other, may have a continuous structure. The first lower and upper chip pads 212 and 222 may be formed of the same material, and there may be no observable or visible interface therebetween. In other words, the first lower and upper chip pads 212 and 222 may be provided as a single element. The first lower and upper chip pads 212 and 222 may be formed of, or include copper (Cu).

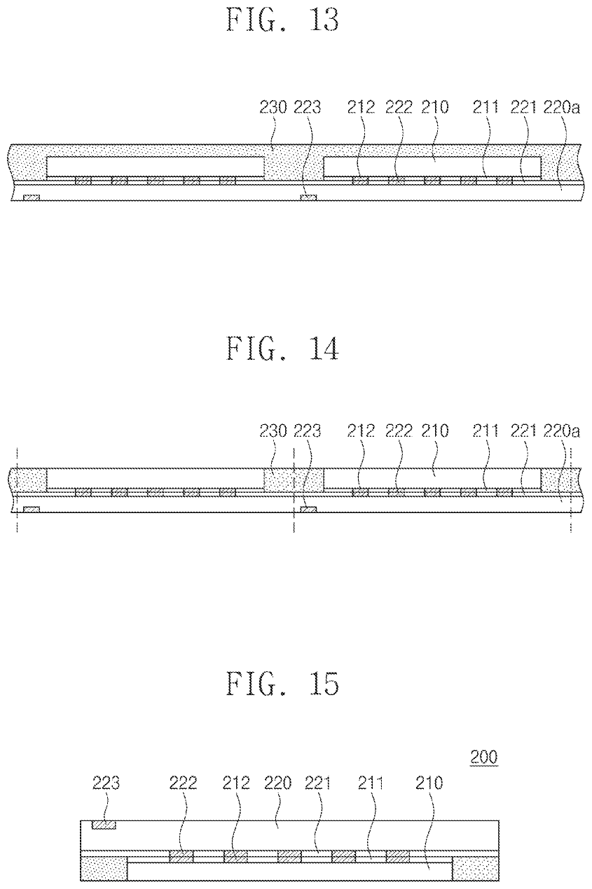

Referring to FIGS. 13 and 14, the insulating layer 230 may be coated on the second wafer 220a to cover the lower structure 210. The insulating layer 230 may be formed to veil or bury the lower structure 210. After the coating of the insulating layer 230, an upper portion of the insulating layer 230 may be partially removed to expose the top surface of the lower structure 210. Alternatively, the insulating layer 230 may not expose the top surface of the lower structure 210.

Referring to FIG. 15, a sawing process may be performed to form the semiconductor structures 200, which are separated from each other. As a result of the sawing process, the second wafer 220a may be divided into the upper structures 220, which are separated from each other. In addition, as a result of the sawing process, a side surface of the upper structure 220 may be vertically aligned to a side surface of the insulating layer 230.

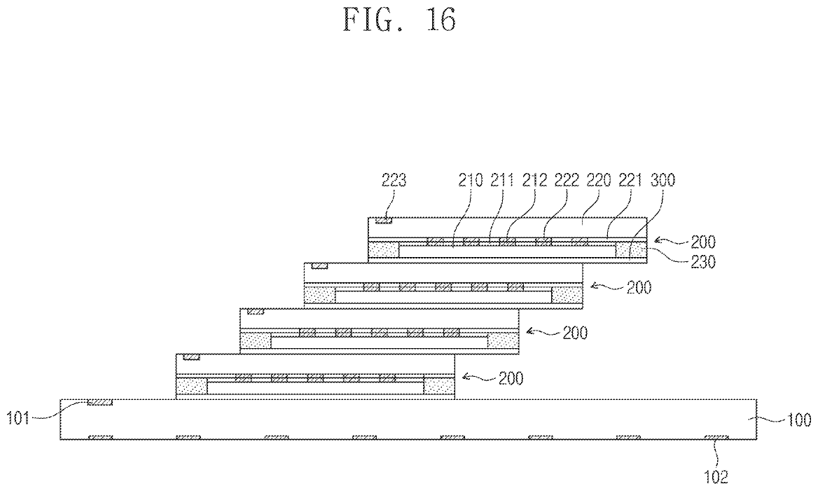

Referring to FIG. 16, the semiconductor structures 200 may be disposed on the substrate 100. The semiconductor structures 200 may be stacked on the substrate 100 in a stepwise manner Each of the semiconductor structures 200 may be attached to the substrate 100 or another one of the semiconductor structures 200 by the adhesive layer 300. In an exemplary embodiment, four or more semiconductor structures 200 may be stacked on the substrate 100.

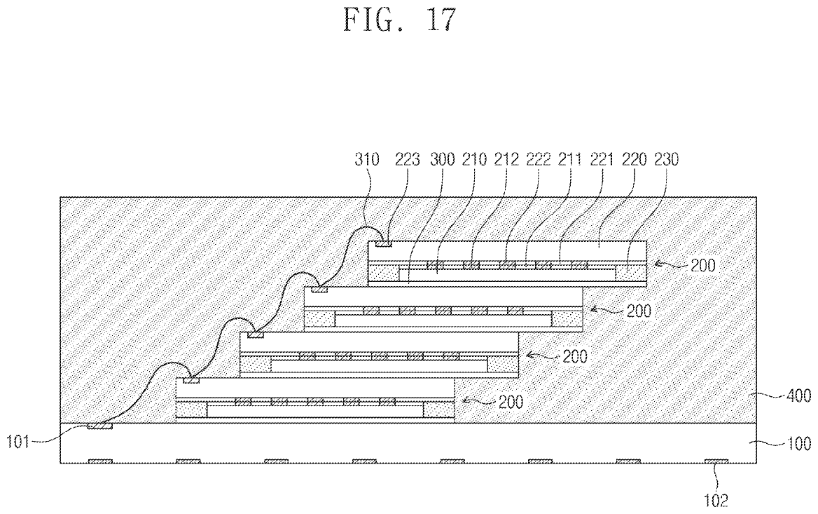

Referring to FIG. 17, the substrate 100 and the semiconductor structures 200 may be connected to each other through the bonding wire 310. The bonding wire 310 may connect the first substrate pad 101 of the substrate 100 to the second upper chip pad 223, which is provided on a top surface of each of the semiconductor structures 200. After the formation of the bonding wire 310, the mold layer 400 may be formed on the substrate 100 to cover the semiconductor structures 200 and the bonding wire 310. In an exemplary embodiment, the mold layer 400 may be formed of, or include at least one of insulating polymers (e.g., epoxy-based molding compound (EMC) or the like).

Referring back to FIG. 1, the semiconductor package 10 of FIG. 1 may be fabricated by disposing the outer connection terminals 103 on the second substrate pad 102, which is provided on the bottom surface of the substrate 100.

According to an exemplary embodiment of the inventive concept, a stack of semiconductor structures may include sub-structures having different planar areas and an insulating layer enclosing the sub-structures. The insulating layer may be used to reduce a height difference between the stacked sub-structures, and in this case, a process of stacking the semiconductor structures may be easily performed. In addition, if necessary, it may be possible to diversify the sizes of the sub-structures, and moreover, it may be possible to improve the yield and productivity of the semiconductor package.

In addition, due to the insulating layer, it may be possible to easily control the warpage issue of the semiconductor package and to improve the heat-dissipation properties of the semiconductor package.

While exemplary embodiments of the inventive concept have been particularly shown and described, it will be understood by one of skill in the art that many variations in form and detail may be made therein without departing from the spirit and scope of the invention as defined in the appended claims. The embodiments of FIGS. 1 to 8 may be combined to realize the inventive concept.

What is claimed is:

1. A semiconductor package, comprising semiconductor structures stacked in a stepwise manner,
wherein each of the semiconductor structures comprises:
a lower structure;
an upper structure on the lower structure; and
an insulating layer provided on a bottom surface of the upper structure to be in contact with at least a portion of side surfaces of the lower structure,
wherein an area of the lower structure is smaller than an area of the upper structure, when viewed in a plan view, and
a side surface of the insulating layer is vertically aligned to a side surface of the upper structure.

2. The semiconductor package of claim 1, wherein the insulating layer is provided to enclose the side surfaces of the lower structure.

3. The semiconductor package of claim 1, wherein the insulating layer is provided to cover one of the side surfaces of the lower structure or to cover two adjacent ones of the side surfaces of the lower structure.

4. The semiconductor package of claim 1, further comprising a supporter, which is provided between the side surface of the insulating layer and one of the side surfaces of the lower structure adjacent thereto and is buried in the insulating layer.

5. The semiconductor package of claim 1, wherein the insulating layer comprises a material whose thermal expansion coefficient is substantially equal to or lower than that of the upper structure.

6. The semiconductor package of claim 1, wherein the insulating layer comprises a material whose thermal conductivity is higher than that of the upper structure.

7. The semiconductor package of claim 1, wherein the lower structure comprises a first chip pad provided on a top surface of the lower structure,
the upper structure comprises a second chip pad provided on a bottom surface of the upper structure, and
the first and second chip pads are in contact with each other to form a single element.

8. The semiconductor package of claim 1, wherein the upper structure comprises a cell array structure, and
the lower structure comprises a peripheral circuit structure.

9. The semiconductor package of claim 1, further comprising:
a substrate, on which the semiconductor structures are disposed;
bonding wires provided to connect a substrate pad and chip pads, which are respectively disposed on a top surface of the substrate and top surfaces of the semiconductor structures, to each other; and
a mold layer provided on the substrate to cover the semiconductor structures.

10. A semiconductor package, comprising:
a substrate including substrate pads provided on a top surface thereof;
substrate connection terminals provided on a bottom surface of the substrate;
semiconductor structures stacked on the substrate, the semiconductor structures comprising chip pads on top surfaces of the semiconductor structures;
bonding wires connecting the substrate pads to the chip pads; and
a mold layer provided on the substrate to cover the semiconductor structures,
wherein each of the semiconductor structures comprises:
a lower structure;
an upper structure disposed on the lower structure, the lower structure exposing a portion of a bottom surface of the upper structure; and
an insulating layer provided on the exposed portion of the bottom surface of the upper structure,
wherein the semiconductor package further comprises a supporter, which is disposed between a side surface of the insulating layer and one of side surfaces of the lower structure and is buried in the insulating layer.

11. The semiconductor package of claim 10, wherein an area of the lower structure is smaller than an area of the upper structure, when viewed in a plan view.

12. The semiconductor package of claim 10, wherein the side surface of the insulating layer is vertically aligned to a side surface of the upper structure.

13. The semiconductor package of claim 10, wherein the insulating layer is provided to cover the side surfaces of the lower structure.

14. The semiconductor package of claim 10, wherein the insulating layer is provided to cover one of the side surfaces of the lower structure or to cover two adjacent ones of the side surfaces of the lower structure.

15. The semiconductor package of claim 10, wherein the upper structure comprises a cell array structure, and
the lower structure comprises a peripheral circuit structure.

16. The semiconductor package of claim 10, wherein each of the semiconductor structures is offset from another one of the semiconductor structures disposed thereunder in a first direction parallel to a top surface of the substrate.

17. A semiconductor package, comprising semiconductor structures stacked in a stepwise manner,
wherein each of the semiconductor structures comprises:
a cell array structure;
a peripheral circuit structure disposed on the cell array structure; and
an insulating layer provided on the cell array structure to enclose a side surface of the peripheral circuit structure,
wherein the cell array structure comprises:
electrode layers stacked on a first substrate;
a channel region provided to vertically penetrate the electrode layers;
a first interlayer insulating layer covering the electrode layers and the channel region; and
first chip pads, which are exposed to an outside of the first interlayer insulating layer and are connected to the electrode layers and the channel region,
wherein the peripheral circuit structure comprises:
at least one transistor provided on a second substrate;
a second interlayer insulating layer covering the at least one transistor; and
second chip pads, which are exposed to an outside of the second interlayer insulating layer and are connected to the transistor,
wherein the first and second chip pads are in contact with each other to form a single element.

18. The semiconductor package of claim 17, wherein an area of the cell array structure is larger than an area of the peripheral circuit structure, when viewed in a plan view.

19. The semiconductor package of claim 17, wherein a side surface of the insulating layer is vertically aligned to the side surface of the peripheral circuit structure.

20. The semiconductor package of claim 17, wherein the cell array structure further comprises a memory cell array, and
the memory cell array comprises:
cell strings including memory cells;
word lines connected to the memory cells, respectively;
bit lines connected to the cell strings; and
a ground selection line connected to the cell strings.
